(19) United States
(12) Patent Application Publication
(10) Pub. No.: US 2025/0238769 A1
(43) Pub. Date: Jul. 24, 2025

(54) PROVISION OF MAINTENANCE DATA

(71) Applicant: KONE Corporation, Helsinki (FI)

(72) Inventors: Gabriela ROIVAINEN, Helsinki (FI); Sanni SILTANEN, Helsinki (FI)

(73) Assignee: KONE Corporation, Helsinki (FI)

(21) Appl. No.: 19/066,635

(22) Filed: Feb. 28, 2025

Related U.S. Application Data
(63) Continuation of application No. PCT/FI2022/050695, filed on Oct. 19, 2022.

(51) Int. Cl. G06Q 10/20; G06F 30/20; G06T 19/00

(52) U.S. Cl. CPC G06Q 10/20; G06F 30/20; G06T 19/006

(57) ABSTRACT

A method generates information descriptive of a maintenance of a people conveyor system is provided. The method includes: receiving data descriptive of a state of a people conveyor system; obtaining data defining a digital twin; simulating an operation of the people conveyor system with the digital twin; obtaining extended reality data based on the simulation; and generating a message to a terminal device, the message including information descriptive of the maintenance of the people conveyor system. A control system and a computer readable medium storing a computer program are also provided.

### TECHNICAL FIELD

The invention concerns in general the technical field of people conveyor systems. More particularly, the invention concerns provision of maintenance data of the people conveyor system.

### BACKGROUND

Different types of people conveyor systems, such as elevators, escalators, and moving walkways, need maintenance either in accordance with a predefined maintenance plan or in response to an unexpected situation. The traditional way to arrange the maintenance is that a technician visits the site in accordance with a need and perform regular checks and/or visits the site in response to a call descriptive of a malfunctioning people conveyor system. Also solutions in which an operation of the people conveyor system is monitored remotely have been introduced. Such approaches rely e.g. on that the data centre receives a fault notification from the people conveyor system and the technician travels to the site and attempts to perform required maintenance tasks to get the people conveyor system repaired.

The solutions as such are operative but they also have drawbacks due to various reasons. For example, depending on the required maintenance task it may happen that the technician sent to the site cannot manage solving the situation due to a lack of required knowledge/competence and/or he/she does not have required tools and/or spare parts with him/her. As a result, the maintenance task delays and that causes dissatisfaction among the users of the people conveyor system.

Therefore, there is a need to introduce novel approaches mitigating at least in part the drawbacks of the prior art solutions.

### SUMMARY

The following presents a simplified summary in order to provide basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

An object of the invention is to present a method, a control system and a computer program for generating information descriptive of a maintenance of a people conveyor system.

The objects of the invention are reached by a method, a control system and a computer program as defined by the respective independent claims.

According to a first aspect, a method for generating information descriptive of a maintenance of a people conveyor system is provided, the method, performed by a control system, comprises:
receiving data descriptive of a state of a people conveyor system,
obtaining data defining a digital twin corresponding to at least part of the people conveyor system,
simulating an operation of the people conveyor system with the digital twin with the data descriptive of the state of the people conveyor system,
obtaining extended reality data based on the simulation of the operation of the people conveyor system with the digital twin,
generating a message to a terminal device, the message comprising information descriptive of the maintenance of the people conveyor system in a data package comprising at least the extended reality data in relation to the state of the people conveyor system.

The method may further comprise, prior to generating the message, a step of:
obtaining data descriptive of components based on the simulation of the operation of the people conveyor system with the digital twin.

For example, the data descriptive of the components may be included in the generated message with the extended reality data.

Still further, the data descriptive of the state of the people conveyor system may be at least one of: measurement data obtained from the people conveyor system; a fault code obtained from the people conveyor system.

The people conveyor system may e.g. be identified from the data descriptive of the state of the people conveyor system. Identification data of the people conveyor system may be used for obtaining the data defining the digital twin of the people conveyor system. For example, the fault code may be used together with the identification data for obtaining data defining the digital twin corresponding to the at least part of the people conveyor system. Moreover, the fault code may be used for selecting the digital twin defining a sub-entity of the people conveyor system.

At least one component being related to the state of the people conveyor system may be identified by simulating an operation of the digital twin with the data descriptive of the state of the people conveyor system. For example, information on the at least one component may be included in the data descriptive of components in relation to the state of the people conveyor system. Still further, the extended reality data based on the simulation of the operation of the digital twin may be selected on a basis of the identified at least one component being related to the state of the people conveyor system. The extended reality data may provide visualization descriptive of a maintenance operation with respect to the at least one component.

The extended reality data may be one of: augmented reality data, virtual data.

According to a second aspect, a control system for generating information descriptive of a maintenance of a people conveyor system is provided, the control system configured to:
receive data descriptive of a state of a people conveyor system,
obtain data defining a digital twin corresponding to at least part of the people conveyor system,
simulate an operation of the people conveyor system with the digital twin with the data descriptive of the state of the people conveyor system,
obtain extended reality data based on the simulation of the operation of the people conveyor system with the digital twin,
generate a message to a terminal device, the message comprising information descriptive of the maintenance of the people conveyor system in a data package comprising at least the extended reality in relation to the state of the people conveyor system.

The control system may also, prior to generating the message, be configured to:
obtain data descriptive of components based on the simulation of the operation of the people conveyor system with the digital twin.

For example, the control system may be configured to include the data descriptive of the components in the generated message with the extended reality data.

The control system may be configured to receive at least one of: measurement data obtained from the people conveyor system; a fault code obtained from the people conveyor system, as the data descriptive of the state of the people conveyor system.

Further, the control system may be configured to identify the people conveyor system from the data descriptive of the state of the people conveyor system.

The control system may also be configured to use identification data of the people conveyor system for obtaining the data defining the digital twin of the people conveyor system. Still further, the control system may be configured to use the fault code together with the identification data for obtaining data defining the digital twin corresponding to the at least part of the people conveyor system. The control system may e.g. be configured to use the fault code for selecting the digital twin defining a sub-entity of the people conveyor system.

Still further, the control system may be configured to identify at least one component being related to the state of the people conveyor system by simulating an operation of the digital twin with the data descriptive of the state of the people conveyor system. For example, the control system may be configured to include information on the at least one component in the data descriptive of components in relation to the state of the people conveyor system. Moreover, the control system may be configured to select the extended reality data based on the simulation of the operation of the digital twin on a basis of the identified at least one component being related to the state of the people conveyor system. For example, the extended reality data may provide visualization descriptive of a maintenance operation with respect to the at least one component.

The extended reality data may be one of: augmented reality data, virtual data.

According to a third aspect, a computer program comprising instructions which, when the program is executed by a computer, cause the computer to carry out the steps of the method according to the first aspect as defined above.

The expression “a number of” refers herein to any positive integer starting from one, e.g. to one, two, or three.

The expression “a plurality of” refers herein to any positive integer starting from two, e.g. to two, three, or four.

Various exemplifying and non-limiting embodiments of the invention both as to constructions and to methods of operation, together with additional objects and advantages thereof, will be best understood from the following description of specific exemplifying and non-limiting embodiments when read in connection with the accompanying drawings.

The verbs “to comprise” and “to include” are used in this document as open limitations that neither exclude nor require the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF FIGURES

The embodiments of the invention are illustrated by way of example, and not by way of limitation, in the figures of the accompanying drawings.

FIG. 1 illustrates schematically a system according to an example.

FIG. 2 illustrates schematically a method according to an example.

FIG. 3 illustrates schematically a control system according to an example.

### DESCRIPTION OF THE EXEMPLIFYING EMBODIMENTS

The specific examples provided in the description given below should not be construed as limiting the scope and/or the applicability of the appended claims. Lists and groups of examples provided in the description given below are not exhaustive unless otherwise explicitly stated.

Generally speaking the present invention relates to a provision of information descriptive of a maintenance of the people conveyor system. The provision of the information may relate to a maintenance visit or to a training of personnel, for example. The solution is based on using a so-called digital twin in determining a state of a people conveyor system, such as a fault situation, and details, such as a root cause in relation to that, and based on that to generate a message carrying a data package comprising extended reality data among other data, such as a fault type, identities of the number of faulty operating components, etc., as the information descriptive of the maintenance of the people conveyor system.

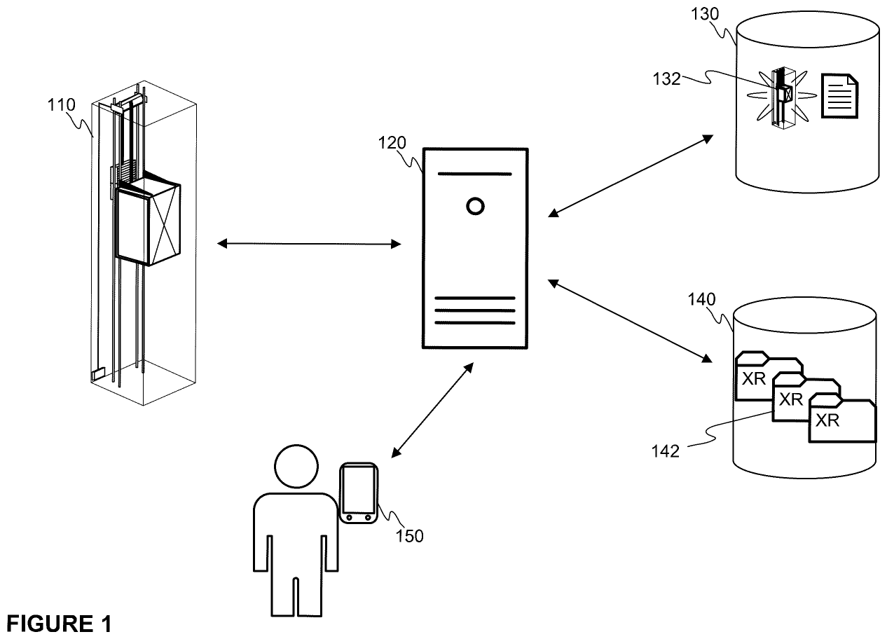

FIG. 1 illustrates schematically an example of an environment as a system into which the present invention may be implemented to as well as examples of entities being involved in implementing the present invention. First, there are a number of people conveyor systems 110 operating in one or more locations. The people conveyor systems 110 may refer to elevators, escalators, and/or moving walkways, or any combination of these. The people conveyor system 110 in question be configured to provide data descriptive on a state of the people conveyor system 110. The provision may be arranged to occur upon a request e.g. from a control system 120 and/or it may be triggered by the people conveyor system 110 itself. The data descriptive of the state of the people conveyor system may refer to measurement data. The measurement data may e.g. be obtained with a number of sensors from the people conveyor system 110 or it may be a number of values descriptive of operational parameters of the conveyor system 110 obtainable from the people conveyor system 110. For sake of clarity it is worthwhile to mention that the data descriptive of the state of the people conveyor system 110 may be such that it describes overall operation of the people conveyor system 110 or an operation, or operations, of one or more entities of the people conveyor system 110, such as an operation of an elevator car, an operation of an electric motor of the respective people conveyor system 110, an operation of elevator brakes, an operation of elevator doors, and so on. Monitored parameters may e.g. be a speed, an acceleration, or any other corresponding parameter of the respective entity. For example, based on the measurement data it may be possible to detect a fault occurring in the people conveyer system 110 or even a wearing state of at least one component as non-limiting examples. In some example embodiments, the data descriptive on the state of the people conveyor system 110 may be one or more fault codes generated by the people conveyor system 110 e.g. upon a detection of a malfunctioning of the system 110. The fault code may be descriptive on a malfunctioning entity of the people conveyor system 110 and it may be delivered alone or together with other data, such as with the measurement data or similar.

An entity arranged to receive the data descriptive on the state of the people conveyor system 110 is a control system 120 in accordance with the present invention. The control system 120 may e.g. be implemented as one or more server devices, or any computing device configured to execute a method according to the invention as is described herein. In other words, the control system 120 may be communicatively connected to the people conveyor system 110, and the entities therein, either directly or indirectly over the other entities in order to get the data. The communication connection may also be arranged so that it is bi-directional, i.e. the control system 120 may sent signals towards the conveyor system 110 e.g. for requesting data therefrom as a non-limiting example.

Furthermore, the control system 120 may be configured to be communicatively connected to a number of data storages 130, 140. In the non-limiting example as shown in FIG. 1 the number of the data storages 130, 140 is two wherein the first data storage is arranged to store data defining so-called digital twins 132 for the number of people conveyor systems 110. In other words, it is arranged that for the people conveyor system 110 a respective digital twin data 132 is stored in the data storage 130. For the purpose of the present invention the digital twin 132 shall be understood as a virtual representation of the real-world people conveyor system 110 i.e. In other words, it is a digitally implemented model of the people conveyor system 110 which may be used for simulating the operation of the people conveyor system 110 and containing of an amount of additional data defining the people conveyor system 110. Such additional data may e.g. be a list of components used in the implementation of the people conveyor system 110 in the real-world. Additionally, the additional data may define a list of tools required to perform a maintenance of the people conveyor system 110 e.g. under the circumstances. All in all, the digital twin 132 may be generated by means of computer-aided design when the people conveyor system 110 is designed and defined as a digital data which may be read and executed by a computer. In some example embodiments, the digital twin 132 as the simulation model of the people conveyor system 110 may be implemented as a machine-learning model trained to output data indicative of an operation of the people conveyor system 110 in response to a receipt of data, such as measurement data, derived from the people conveyor system 110 e.g. with a monitoring system comprising one or more sensors, for example. The training of such machine learning model may be performed with data generated with a simulation model of the people conveyor system 110 and/or with other data, such as measurement data from the respective system and e.g. with so-called back-reports received from persons maintaining the people conveyor system 110, for example.

Moreover, the control system 120 may be arranged to be communicatively connected to at least one other data storage 140. The second data storage 140 may be arranged to store so called extended reality data 142. The extended reality data may refer to a virtual reality data and/or to an augmented reality data, for example. The extended reality data 142 stored in the data storage 140 may comprise a plurality of data files and the data is associated to various parts of the people conveyor system 110. In other words, the extended reality data 142 may represent one or more components of the people conveyor system 110 and/or provide output disclosing maintenance operations with respect to the one or more components of the conveyor system 110. For example, if the extended reality data is a collection of data files representing information in the virtual reality it may e.g. define instructions how a certain component may be replaced in the people conveyor system 110. Alternatively or in addition, it may visualize, or allow the viewer to see, an operable assembly of a certain sub-entity of the people conveyor system 110, for instance. On the other hand, if the extended reality data is augmented reality data it may define visualizations integrable in the real-world visualization captured in any known manner. In the context of the present invention the augmented reality data may e.g. visualize, such as highlight, a faulty operating component in a visualization of the real-world when an image capturing device is headed to capture an image from the respective component. For the purpose of the present invention, the extended reality data 142 is something by means of which a user may be provided with enhanced information compared to the real-world view. The data stored in the second data storage 140 may be classified so that different data files may be inquired with a predefined parameters, such as keywords or any other identifiers. For sake of completeness, it is worthwhile to mention that the communication connection between the control system 120 and the number of data storages 130, 140 may be arranged to be bidirectional i.e. the control system 120 may inquire data from the data storages 130, 140 but also to store data therein. Also unidirectional communication may also be applied to as long as the control system 120 may obtain the data stored in the respective data storages 130, 140. As already mentioned, the system as shown in FIG. 1 may comprise one or more data storages 130, 140 as long as the data described herein may be inquired from the setup.

Still further, the control system 120 may be communicatively connected to one or more terminal devices 150, which may e.g. be terminal devices 150 used by technicians maintaining the conveyor system 110. Such devices may e.g. be mobile phones, tablet computers, laptop computers, PCs, virtual glasses, wearable devices or any other type of display devices communicatively connectable with the control system 120. The terminal devices 150 in question are capable of generating the extended reality content either remotely or on site depending on the implementation.

The communication connection referred to above may be implemented either by using a wired communication technology, a wireless communication technology, or any combination of these two. For example, wireless communication networks, such as mobile communication networks may be utilized e.g. in communicating with the terminal devices 150. Moreover, the entities, especially the people conveyor system 110, the control system 120 and the one or more data storages 130, 140 may reside at the same location, remotely, or combining these approaches in any applicable manner.

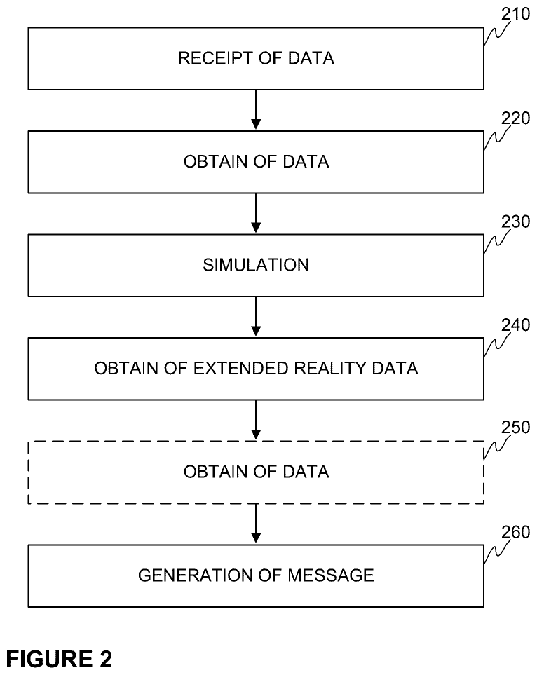

FIG. 2 illustrates schematically an example of a method implemented by the control system 120 communicatively connected with the other entities as described. The aim of the method is to generate information descriptive of a maintenance of a people conveyor system 110. Such information may e.g. be information enabling identification objects, such as components, from the people conveyor system 110, information enabling maintenance task of the people conveyor system 110, information listing relevant components in relation to the maintenance task, or any combination of these and other corresponding information.

In step 210, the control system 120 receives data descriptive of a state of a people conveyor system 110. As already mentioned, the data descriptive of the state of the people conveyor system 110 may refer to measurement data. The data descriptive of the state of the people conveyor system 110 may also carry data identifying the people conveyor system 110. Alternatively or in addition, the data descriptive of the people conveyor system 110 may be descriptive of a malfunctioning of the people conveyor system 110, such as a fault code e.g. together with the data identifying the people conveyor system 110.

In response to the receipt 110 of the data descriptive of the state of the people conveyor system 110 the control system 120 may obtain 220 data defining a digital twin 132 corresponding to at least part of the people conveyor system 110 from which the data is received 210. The obtainment 220 of the data defining the digital twin 132 may be performed by inquiring the data from the data storage 130, 140 arranged to store such data. The inquiry may carry data identifying the people conveyor system 110, or at least a sub-entity of it, to enable the data storage 130, 140 to return a digital twin data 132 corresponding to the one based on which the inquiry is made. As mentioned, the data identifying the people conveyor system 110 may be received in the step 210. As a result of the inquiry the data storage 130, 140 returns the digital twin data 132, i.e. the digital model of the people conveyor system 110, or a part of it, to the control system 120. As said, the digital twin data 132 may also define a machine learning model of the people conveyor system 110, or part of it, configured to perform an operation considered as a simulation by means of the input data.

In response to the receipt of the digital twin data 132 the control system 120 may be configured to simulate 230 an operation of the digital twin 132 with the data descriptive of the state of the people conveyor system 110. This may correspond to an arrangement in which the control system 120 is configured to read and execute the data defining the digital twin 132 of the respective people conveyor system 110 i.e. at least to simulate the operation of the people conveyor system 110 with the digital twin 132 model. The simulation 230 in accordance with the present invention may be performed so that the data descriptive of a state of a people conveyor system 110 received is input as one or more parameters into the digital twin 132 model which causes the digital twin 132 model to resemble the real people conveyor system 110 in operation. Moreover, in some embodiments the simulation 230 comprises an input of the data descriptive of the state of the people conveyor system 110 to a machine learning model trained to identify root causes of an operation of the people conveyor system 110 in a deviating manner, if any. By performing the simulation 230 in the described manner it is possible, by computational measures, to detect deviation in operation to a simulation model arranged to operate in an optimal, or desired, manner, and this kind of approach enables identifying one or more root causes for the deviated operation. The root cause may e.g. be a malfunction of one or more components, or a component assembly, in the people conveyor system 110. Thus, as a result of the simulation 230 one or more entities of the people conveyor system 110 operating in a deviating way compared to the reference may be identified. The outcome of the simulation 230 may also be a generation of data indicative of a list of a maintenance tasks required to be conducted in order to correct the deviancy in the operation. Such list may e.g. list the maintenance tasks with predefined codes, or similar, so as to enable at least an internal use of them by the control system 120 in the further steps of the method. The term maintenance task shall be understood in a broad manner to cover also a list of root causes of the deviating operation in accordance with some example embodiments of the invention.

In the above described approach the digital twin 132 is considered to be a system level model of the people conveyor system 110, but in some other approaches the digital twin 132 may correspond to at least part of the people conveyor system 110. In other words, the digital twin 132 of the people conveyor system 110 may be defined as a collection of sub-models of the people conveyor system 110, i.e. as sub digital twins 132. In such an approach the plurality sub digital twins 132 may be models of a plurality of sub-entities of the people conveyor system 110 of a certain people conveyor system 110. In this kind of approach, for example, a fault code received in the step 210 as described may be used, e.g. together with the data identifying the people conveyor system 110, for obtaining 220, such as selecting, the data defining the digital twin 132 correspond to the sub-entity of the people conveyor system 110 for the simulation 230. For example, the fault code may e.g. indicate that the elevator car experiences an unallowable amount of vibration and as a result one or more sub digital twins 132 defined to be related to the vibration of the elevator car may be obtained to be used in the simulation. For example, one such sub digital twin 132 may be descriptive of an operation of bearings of an electric motor or any pulleys over which the elevator roping runs over. This kind of approach may lead more accurately to the actual root causes of the malfunctioning in a more efficient way and into a selection of accurate extended reality data 142 with any other data as is described in the forthcoming description.

Namely, in response to the simulation 230 and a detection of one or more root causes the control system 240 is configured obtain 240 a so-called extended reality data 142 based on the simulation 230 of the operation of the people conveyor system 110 from a respective data storage 130, 140. The obtaining 240 of the extended reality data 142 may refer to a mechanism in which the control system 120 includes, as a parameter, some piece of data obtained in the simulation 230 descriptive of an entity of the people conveyor system 110 malfunctioning therein. Such data may e.g. be at least a portion of the simulation data, or at least the result data of the simulation 230. In some other embodiments the data may directly identify one or more entities, such as components of the people conveyor system 110 malfunctioning on the basis of detections made in the simulation 230. Alternatively or in addition, the data may identify maintenance task or tasks, if such are derived in the simulation 230 phase. As said, the aim of the step 240 of the method is to receive extended reality data 142 in response to the inquiry to the data storage 130, 140 wherein the extended reality data 142 is related in a predefined manner to the detected aspects in the operation of the people conveyor system 110. For example, the relation may correspond to a detection of the one or more entities of the people conveyor system 110 identified to be involved in the malfunctioning of the people conveyor system 110 and the obtained extended reality data 142 represents in some manner measures with respect to the identified entities, such as components of the people conveyor system 110. For example, the extended reality data 142 may be descriptive of a maintenance task required to be performed to the identified entity in order to solve the malfunctioning situation. Depending on the sub-type of the extended reality data 142 it may be data highlighting some components visually in a representation or it may be guidance to perform the maintenance task. For example, the extended reality data 142 may be augmented reality data integrable with real-world visualization or it may be virtual reality data representing the real-world matters in virtual space as is commonly known. The extended reality data may be implemented as animations, videos, or simulations. For example, the animations may be considering mainly dimensional limitation (so components are not colliding), videos may be recorded instructions and simulations may be animations that take into account physics outputs like displacement, speed, current, etc. and, therefore, may be considered more accurate, i.e. closer to reality.

Still further, in some example embodiments the control system 120 may also be configured to obtain 250 data descriptive of components based on the simulation of the operation of the people conveyor system 110 with the digital twin 132. In other words, the simulation may generate a list of components related, or at least assumed to be related to the deviating operation of the people conveyor system 110 based on the simulation with the simulation model, i.e. with the digital twin 142. The list of components may also define one or more tools required to perform the maintenance operation with respect to the people conveyor system 110, and the components therein. As said and as indicated with the dashed line in FIG. 2 the step 250 may be optional and be e.g. dependent on an application area of the invention. For example, in case the invention is used for preparing a technician to a maintenance visit the step 250 may be implemented in order to generate a list of items the technician shall take with him for the visit. On the other hand, if the invention is used for training purposes the step 250 is not necessary to be implemented. Hence, in some example embodiments the method is implemented so that the process goes directly from the step 240 to the step 260.

In response to the previous steps the control system 120 is ready for generating 260 a message to a terminal device 150 e.g. possessed by a technician. The message is generated 260 so that it comprises information descriptive of the maintenance of the people conveyor system 110 in a data package comprising at least the extended reality data 142, but also the data descriptive of components in accordance with some embodiments, in relation to the state of the people conveyor system 110. The generation 260 of the message shall be understood to cover any methods of generating the message in terms of various possibilities to deliver and to provide data to the recipient, i.e. using a point to point communication or utilization of any applications e.g. applying cloud computing environment. The data in the message may be executed by the terminal device 150 so that the information descriptive of a maintenance of a people conveyor system 110 may be generated. For sake of clarity it is worthwhile to mention that in the context of the present invention the generation 260 of the message may also be implemented so that data comprising the extended reality data included in the data package is a network link to a storage arranged to store the respective extended reality data. The storing, or a determination of the location of the storing, may e.g. be performed in the step 240 described above. In other words, the extended reality data in the data package may either be the extended reality data itself or a network link to a network location storing the respective extended reality data. The recipient may access the data with her/his terminal device 150 accordingly. The approach in which the extended reality data, but also the data descriptive of the components, are stored in a data storage accessible with the network link, or with network links, included in the data package has an advantage that an amount of data delivered in the message is optimized, such as minimized, which saves communication resources as well as memory resources especially in the terminal device. In view of above the term data package shall be understood as a vehicle to carry the desired piece, or pieces of data, between the control system 120 and the terminal device 150.

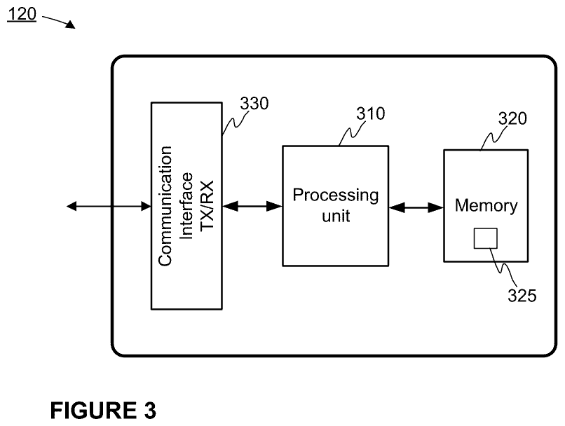

An example of such an apparatus configurable to implement the operation of the control system 120 is schematically illustrated in FIG. 3. The control system 120 may be configured to perform the method according to the invention as described with the examples in the foregoing description. Thus, the apparatus of FIG. 3 may be configured to perform a generation of information descriptive of a maintenance of a people conveyor system 110. For sake of clarity, it is worthwhile to mention that the block diagram of FIG. 3 depicts some components of an entity that may be employed to implement a functionality of the apparatus. The apparatus of FIG. 3 comprises a processor 310 and a memory 320. The memory 320 may store data, such as pieces of data as described, but also computer program code 325 causing the association in the described manner. The apparatus may further comprise a communication interface 330, such as a wireless communication interface or a communication interface for wired communication, or both to communicate with other entities as described. The communication interface 330 may thus comprise one or more modems, antennas, and any other hardware and software for enabling an execution of the communication e.g. under control of the processor 310. Furthermore, I/O (input/output) components may be arranged, together with the processor 310 and a portion of the computer program code 325, to provide a user interface for receiving input from a user, such as from a technician, and/or providing output to the user of the apparatus when necessary. In particular, the user I/O components may include user input means, such as one or more keys or buttons, a keyboard, a touchscreen, or a touchpad, etc. The user I/O components may include output means, such as a loudspeaker, a display, or a touchscreen. The components of the apparatus may be communicatively connected to each other via data bus that enables transfer of data and control information between the components.

The memory 320 and at least a portion of the computer program code 325 stored therein may further be arranged, with the processor 310, to cause the apparatus to perform at least a portion of a method as is described herein. The processor 310 may be configured to read from and write to the memory 320. Although the processor 310 is depicted as a respective single component, it may be implemented as respective one or more separate processing components. Similarly, although the memory 320 is depicted as a respective single component, it may be implemented as respective one or more separate components, some, or all of which may be integrated/removable and/or may provide permanent/semi-permanent/dynamic/cached storage.

The computer program code 325 may comprise computer-executable instructions that implement functions that correspond to steps implemented in the method when loaded into the processor 310 of the respective control system 120. As an example, the computer program code 325 may include a computer program consisting of one or more sequences of one or more instructions. The processor 310 is able to load and execute the computer program by reading the one or more sequences of one or more instructions included therein from the memory 320. The one or more sequences of one or more instructions may be configured to, when executed by the processor 310, cause the apparatus, such as a computer, to perform a method as described. Hence, the apparatus may comprise at least one processor 310 and at least one memory 320 including the computer program code 325 for one or more programs, the at least one memory 320 and the computer program code 325 configured to, with the at least one processor 310, cause the apparatus implementing the control system 120 to perform the method. For sake of completeness, it is worthwhile to mention that at least one portion of the computer program code 325 may correspond to the digital twin 132 of the respective people conveyor system 110 and it may be implemented as the simulation model being e.g. a machine learning model.

The computer program code 325, or at least some portion of it, may be provided e.g. a computer program product comprising at least one computer-readable non-transitory medium having the computer program code 325 stored thereon, which computer program code 325, when executed by the processor 310 causes the apparatus to perform the method. The computer-readable non-transitory medium may comprise a memory device or a record medium, such as a CD-ROM, a DVD, a Blu-ray disc, or another article of manufacture that tangibly embodies the computer program. As another example, the computer program may be provided as a signal configured to reliably transfer the computer program.

Still further, the computer program code 325 may comprise a proprietary application, such as computer program code for causing an execution of the method in the manner as described in the description herein.

Any of the programmed functions mentioned may also be performed in firmware or hardware adapted to or programmed to perform the necessary tasks.

For sake of completeness it is worthwhile to mention that the entity performing the method in the role of the control system 120 may also be implemented with a plurality of apparatuses, such as the one schematically illustrated in FIG. 3, as a distributed computing environment corresponding to a control system. For example, one of the apparatuses may be communicatively connected with the other apparatuses, and e.g. share the data of the method, to cause another apparatus to perform at least one other portion of the method. As a result, the method performed in the distributed computing environment generates the control signal indicative of the assignment of the responsibility as described.

The above described solution may be utilized for various purposes. For example, it may be used for training technicians to perform various maintenance tasks in real-world situations, since the operation of the real-world people conveyor systems 110 is monitored. Thus, the data generated for the technician may be training data expressed at least in part by applying extended reality technology in that. On the other hand, the solution in accordance with the present invention may be applied in a context of the actual maintenance task, or operation. For example, in response to the generated message the technician may prepare for the visit by arranging all the necessary components with her/him, and when entering the site the technician may receive instructions by utilizing the extended reality technology for performing the maintenance task. All these improve the preparation for the maintenance visit as well as doing it.

The specific examples provided in the description given above should not be construed as limiting the applicability and/or the interpretation of the appended claims. Lists and groups of examples provided in the description given above are not exhaustive unless otherwise explicitly stated.

1. A method for generating information descriptive of a maintenance of a people conveyor system, the method, performed by a control system, comprises:
receiving data descriptive of a state of a people conveyor system,
obtaining data defining a digital twin corresponding to at least part of the people conveyor system,
simulating an operation of the people conveyor system with the digital twin with the data descriptive of the state of the people conveyor system,
obtaining extended reality data based on the simulation of the operation of the people conveyor system with the digital twin,
generating a message to a terminal device, the message comprising information descriptive of the maintenance of the people conveyor system in a data package comprising at least the extended reality data in relation to the state of the people conveyor system.

2. The method according to claim 1, the method further comprises, prior to generating the message, a step of:
obtaining data descriptive of components based on the simulation of the operation of the people conveyor system with the digital twin.

3. The method according to claim 2, wherein the data descriptive of the components is included in the generated message with the extended reality data.

4. The method according to claim 1, wherein the data descriptive of the state of the people conveyor system is at least one of: measurement data obtained from the people conveyor system; a fault code obtained from the people conveyor system.

5. The method according to claim 1, wherein the people conveyor system is identified from the data descriptive of the state of the people conveyor system.

6. The method according to claim 5, wherein identification data of the people conveyor system is used for obtaining the data defining the digital twin of the people conveyor system.

7. The method according to claim 6, wherein the fault code is used together with the identification data for obtaining data defining the digital twin corresponding to the at least part of the people conveyor system.

8. The method according to claim 7, wherein the fault code is used for selecting the digital twin defining a sub-entity of the people conveyor system.

9. The method according to claim 1, wherein at least one component being related to the state of the people conveyor system is identified by simulating an operation of the digital twin with the data descriptive of the state of the people conveyor system.

10. The method according to the claim 9, wherein information on the at least one component is included in the data descriptive of components in relation to the state of the people conveyor system.

11. The method according to claim 9, wherein the extended reality data based on the simulation of the operation of the digital twin is selected on a basis of the identified at least one component being related to the state of the people conveyor system.

12. The method according to claim 11, wherein the extended reality data provides visualization descriptive of a maintenance operation with respect to the at least one component.

13. The method according to claim 1, wherein the extended reality data is one of: augmented reality data, virtual data.

14. A control system for generating information descriptive of a maintenance of a people conveyor system, the control system configured to:
receive data descriptive of a state of a people conveyor system,
obtain data defining a digital twin corresponding to at least part of the people conveyor system,
simulate an operation of the people conveyor system with the digital twin with the data descriptive of the state of the people conveyor system,
obtain extended reality data based on the simulation of the operation of the people conveyor system with the digital twin,
generate a message to a terminal device, the message comprising information descriptive of the maintenance of the people conveyor system in a data package comprising at least the extended reality in relation to the state of the people conveyor system.

15. The control system according to claim 14, the control system is, prior to generating the message, configured to:
obtain data descriptive of components based on the simulation of the operation of the people conveyor system with the digital twin.

16. The control system according to claim 15, wherein the control system is configured to include the data descriptive of the components in the generated message with the extended reality data.

17. The control system according to claim 14, wherein the control system is configured to receive at least one of: measurement data obtained from the people conveyor system; a fault code obtained from the people conveyor system, as the data descriptive of the state of the people conveyor system.

18. The control system according to claim 14, wherein the control system is configured to identify the people conveyor system from the data descriptive of the state of the people conveyor system.

19. The control system according to claim 18, wherein the control system is configured to use identification data of the people conveyor system for obtaining the data defining the digital twin of the people conveyor system.

20. The control system according to claim 19, wherein the control system is configured to use the fault code together with the identification data for obtaining data defining the digital twin corresponding to the at least part of the people conveyor system.

21. The control system according to claim 20, wherein the control system is configured to use the fault code for selecting the digital twin defining a sub-entity of the people conveyor system.

22. The control system according to claim 14, wherein the control system is configured to identify at least one component being related to the state of the people conveyor system by simulating an operation of the digital twin with the data descriptive of the state of the people conveyor system.

23. The control system according to the claim 22, wherein the control system is configured to include information on the at least one component in the data descriptive of components in relation to the state of the people conveyor system.

24. The control system according to claim 22, wherein the control system is configured to select the extended reality data based on the simulation of the operation of the digital twin on a basis of the identified at least one component being related to the state of the people conveyor system.

25. The control system according to claim 24, wherein the extended reality data provides visualization descriptive of a maintenance operation with respect to the at least one component.

26. The control system according to claim 14, wherein the extended reality data is one of: augmented reality data, virtual data.

27. A non-transitory computer readable medium storing a computer program comprising instructions which, when the program is executed by a computer, cause the computer to carry out the steps of the method of claim 1.
